(19) United States
(12) Patent Application Publication
(10) Pub. No.: US 2026/0136661 A1
(43) Pub. Date: May 14, 2026

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: YI-YI CHEN, KEELUNG CITY (TW); CHIH-LIANG CHEN, HSINCHU CITY (TW); CHI-YU LU, NEW TAIPEI CITY (TW); YA-CHI CHOU, HSINCHU CITY (TW); CHEN-LING WU, TAOYUAN CITY (TW)

(21) Appl. No.: 18/945,583

(22) Filed: Nov. 13, 2024

(51) Int. Cl. H01L 27/118

(52) U.S. Cl. CPC H10D 84/907; H10D 84/953; H10D 84/975; H10D 84/979; H10D 84/981

(57) ABSTRACT

A semiconductor device and a method of manufacturing the same are provided. The semiconductor device has a cell. The cell includes a gate structure, a first active region, a second active region, a first signal line, and a second signal line. The gate structure extends along a first direction. The first active region extends along a second direction different from the first direction and intersects the gate structure. The second active region extends along the second direction and intersects the gate structure. The first active region overlaps the second active region along a third direction different from the first direction and the second direction. The first signal line is over the first active region and configured to transmit an input signal. The second signal line is under the second active region and configured to transmit an output signal.

### BACKGROUND

Currently, semiconductor devices are widely used in various fields, such as cloud storage, medicine, transportation, mobile devices, etc. The current trend in some aspects of semiconductor device manufacturing focuses on providing semiconductor devices with smaller dimensions and better power efficiency. It is therefore desirable to continuously improve the structure and manufacturing of the semiconductor devices.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1A and FIG. 1B are layout diagrams of a semiconductor device, in accordance with some embodiments.

FIG. 1C, FIG. 1D, and FIG. 1E are cross-sectional views along line A-A′, B-B′, and C-C′ of the semiconductor device as specified by the layout diagrams in FIGS. 1A-1B, in accordance with some embodiments.

FIG. 2A and FIG. 2B are layout diagrams of a semiconductor device, in accordance with some embodiments.

FIG. 3A and FIG. 3B are layout diagrams of a semiconductor device, in accordance with some embodiments.

FIG. 4A and FIG. 4B are layout diagrams of a semiconductor device, in accordance with some embodiments.

FIG. 5A and FIG. 5B are layout diagrams of a semiconductor device, in accordance with some embodiments.

FIG. 6A and FIG. 6B are layout diagrams of a semiconductor device, in accordance with some embodiments.

FIG. 6C and FIG. 6D are layout diagrams of a semiconductor device, in accordance with some embodiments.

FIG. 7A FIG. 7B, and FIG. 7C are layout diagrams of a semiconductor device, in accordance with some embodiments.

FIG. 8A and FIG. 8B are layout diagrams of a semiconductor device, in accordance with some embodiments.

FIG. 9A and FIG. 9B are layout diagrams of a semiconductor device, in accordance with some embodiments.

FIG. 10 is a block diagram of a system of designing a semiconductor device, in accordance with some embodiments.

FIG. 11 is a block diagram of a semiconductor device manufacturing system, and a semiconductor device flow associated therewith, in accordance with some embodiments.

FIG. 12 is a flowchart of a method for manufacturing a semiconductor device according to various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure generally relates to a semiconductor device, and more particularly to a complementary-FET (CFET) with an input pin and an output pin routed from dual sides (e.g., frontside and backside). To improve design density while increasing routing resources simultaneously, the present teaching discloses a three-dimensional (3D) device including CFETs, with both frontside routing and backside routing enabled. While area and cell height are reduced from planar transistor to CFET, the number of metal lines that can be used for routing is also reduced on one side (or dual sides) of a cell. With both frontside routing and backside routing enabled, a CFET cell can achieve high design density without sacrificing routing resources.

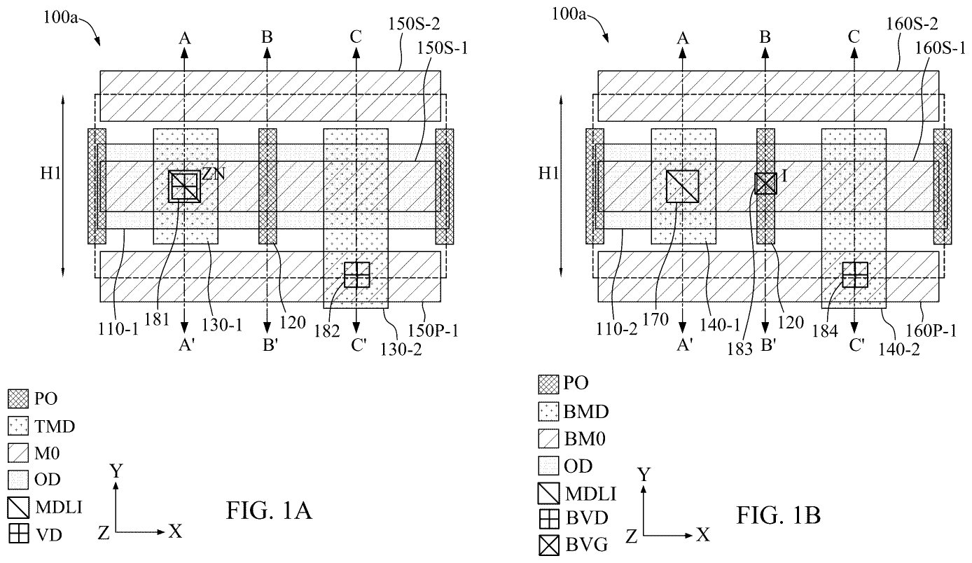

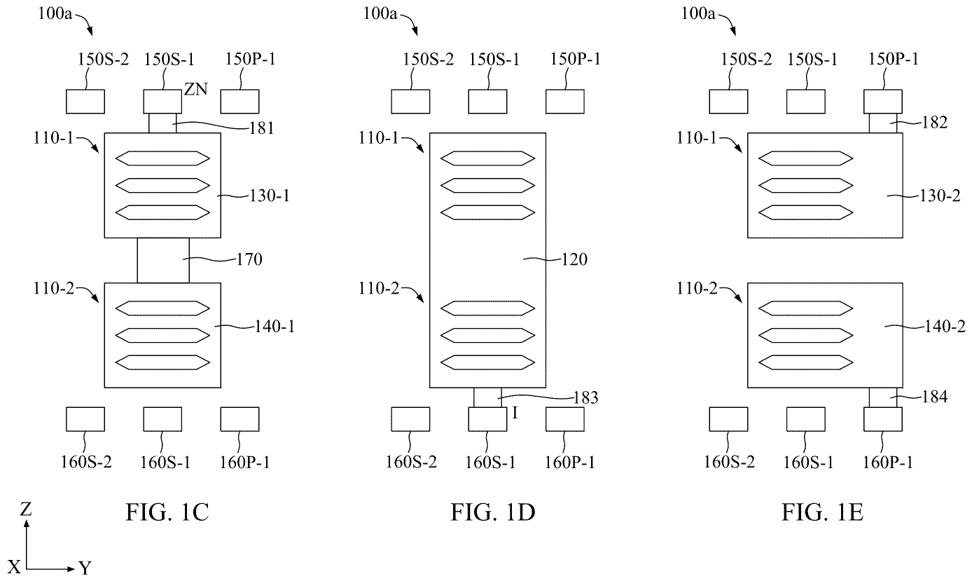

FIG. 1A and B are layout diagrams of a semiconductor device 100a in accordance with some embodiments. FIG. 1A includes the layout patterns for specifying the frontside conductive features, and FIG. 1B includes the layout patterns for specifying the backside conductive features. In some embodiments, the semiconductor device 100a includes a layout of a cell (e.g., a standard cell) of an inverter.

In some embodiments, the semiconductor device 100a includes active regions 110-1 and 110-2 (or active region layout patterns). Each of the active regions 110-1 and 110-2 extends along the X direction. In some embodiments, the active region 110-1 includes the first type (e.g., n-type) active region, and the active region 110-2 includes the second type (e.g., p-type) active region. Non-limiting examples of the active regions 110-1 and 110-2 include nanosheet transistors, nanowire transistors, fin field-effect transistors (FinFETs), or other FETs. In some embodiments, the active region 110-1 overlaps the active region 110-2 along the Z direction. In some embodiments, the active regions 110-1 and 110-2 can be referred to as an oxide definition region (also referred to as “OD”).

The semiconductor device 100a includes a gate structure 120 (or gate layout pattern). The gate structure 120 extends along the Y direction. In some embodiments, the gate structure 120 intersects the active region 110-1 at the channel region of the transistor with the first type, and intersects the active region 110-2 at the channel region of the transistor with the second type. In some embodiments, the gate structure 120 can be referred to as a poly (PO) of a semiconductor device.

The semiconductor device 100a includes contacts 130-1 and 130-2 (or top source/drain (S/D) contact layout patterns). Each of the contacts 130-1 and 130-2 extends along the Y direction. The contacts 130-1 and 130-2 are disposed at the frontside of the semiconductor device 100a. The contacts 130-1 and 130-2 intersect the active region 110-1 at the S/D region of the transistor with the first type. In some embodiments, the contacts 130-1 and 130-2 can be referred to as top metal diffusion (TMD) conductive features of a semiconductor device.

The semiconductor device 100a includes contacts 140-1 and 140-2 (or bottom source/drain (S/D) contact layout patterns). Each of the contacts 140-1 and 140-2 extends along the Y direction. The contacts 140-1 and 140-2 are disposed at the backside of the semiconductor device 100a. The contacts 140-1 and 140-2 intersect the active region 110-2 at the S/D region of the transistor with the second type. In some embodiments, the contacts 140-1 and 140-2 can be referred to as bottom metal diffusion (BMD) conductive features of a semiconductor device.

In some embodiments, the semiconductor device 100a includes signal lines 150S-1 and 150S-2 (or non-power lines). Each of the signal lines 150S-1 and 150S-2 extends along the X direction. In some embodiments, the signal line 150S-1 and/or signal line 150S-2 can be configured to transmit a non-power signal, such as an output signal.

In some embodiments, the semiconductor device 100a includes a power line 150P-1. The power line 150P-1 extends along the X direction. In some embodiments, the power line 150P-1 can be configured to transmit a power signal (or power). In some embodiments, the power line 150P-1 is electrically connected to a logic low power supply or negative power supply (VSS). In some embodiments, the signal line 150S-1, signal line 150S-2, and power line 150P-1 constitute the metal zero (M0) layer of the semiconductor device 100a. In some embodiments, the signal line 150S-2 is located at a cell boundary of the cell and can be shared with another cell. In some embodiments, the power line 150P-1 is located at a cell boundary of the cell and can be shared with another cell. In some embodiments, the ratio of the width of the power line 150P-1 to the width of the signal line 150S-1 (or signal line 150S-2) along the Y direction ranges from about 1 to about 2.5, such as 1, 1.5, 2, or 2.5.

In some embodiments, the semiconductor device 100a includes signal lines 160S-1 and 160S-2 (or non-power lines). Each of the signal lines 160S-1 and 160S-2 extends along the X direction. In some embodiments, the signal line 160S-1 and/or 160S-2 can be configured to transmit a non-power signal, such as an output signal.

In some embodiments, the semiconductor device 100a includes a power line 160P-1. The power line 160P-1 extends along the X direction. In some embodiments, the power line 160P-1 can be configured to transmit a power signal (or power). In some embodiments, the power line 160P-1 is electrically connected to a logic high power supply or positive power supply (VDD). In some embodiments, the signal line 160S-1, signal line 160S-2, and power line 160P-1 constitute the backside metal zero (BM0) layer of the semiconductor device 100a. In some embodiments, the signal line 160S-2 is located at a cell boundary of the cell and can be shared with another cell. In some embodiments, the power line 160P-1 is located at a cell boundary of the cell and can be shared with another cell. In some embodiments, the ratio of the width of the power line 160P-1 to the width of the signal line 160S-1 (or 160S-2) the along the Y direction ranges from about 1 to about 2.5, such as 1, 1.5, 2, or 2.5.

In some embodiments, the width of the signal line 150S-1 is substantially equal to that of the signal line 160S-1. In some embodiments, the width of the power line 150P-1 is substantially equal to that of the power line 160P-1.

In some embodiments, the power line 150P-1 overlaps the power line 160P-1 along the Z direction. In some embodiments, the signal line 150S-1 overlaps the signal line 160S-1 along the Z direction. In some embodiments, the power line is free from overlapping the signal line along the Z direction.

The semiconductor device 100 a includes a via 170 (or interconnection or interconnection layout pattern). The via 170 can be configured to electrically couple the TMD and the BMD. For example, the via 170 electrically connects the contact 130-1 and contact 140-1. In some embodiments, the via 170 can be referred to as “MDLI.”

The semiconductor device 100a includes vias 181, 182, 183, and 184 (or interconnections). The via 181 and via 182 can be configured to electrically couple the TMD and the M0. For example, the via 181 electrically connects the contact 130-1 and signal line 150S-1. The via 182 electrically connects the contact 130-2 and power line 150P-1. In some embodiments, the via 181 and via 182 can be referred to as “VD.” The via 183 can be configured to electrically couple the PO and the BM0. For example, the via 183 electrically connects the gate structure 120 and signal line 160S-1. In some embodiments, the via 183 can be referred to as “BVG.” The via 184 can electrically couple the BMD and the BM0. For example, the via 184 electrically connects the contact 140-2 and power line 160P-1. In some embodiments, the via 184 can be referred to as “BVD.”

In some embodiments, the input pin I of the semiconductor device 100a is routed from the gate structure 120 through the signal line 160S-1 at the backside. In some embodiments, the output pin ZN of the semiconductor device 100a is routed from the contact 130-1 through the signal line 150S-1 at the frontside. In addition, a VDD is provided to the semiconductor device 100a through the power line 160P-1 at the backside; and a VSS is provided to the semiconductor device 100a through the power line 150P-1 at the frontside.

In some embodiments, the cell height H1 of the semiconductor device 100a is satisfied with an equation: H1=1.5×A+0.5×B+2×C, wherein A is a width of the signal line along the Y direction, B is a width of the power line along the Y direction, and C is a space (or distance along the Y direction) between the abutting two layers of the M0 layer. For example, C is equal to the distance between the signal line 150S-1 and power line 150P-1.

FIGS. 1C, 1D, and 1E are cross-sectional views along line A-A′, B-B′, and C-C′ of the semiconductor device 100a in accordance with some embodiments.

As shown in FIG. 1C, the via 170 is disposed between the active regions 110-1 and 110-2 to connect the contacts 130-1 and 140-1. The signal line 150S-1 can function as the output pin ZN at the frontside of the semiconductor device 100a. In some embodiments, the via 170 overlaps the signal line 150S-1 along the Z direction. In some embodiments, the via 170 overlaps the via 181 along the Z direction. As shown in FIG. 1D, the signal line 160S-1 is coupled to the gate structure 120 through the via 182 and can function as an input pin I at the backside of the semiconductor device 100a. In some embodiments, the semiconductor device 100a has a via 183 connecting a VSS through the power line 150P-1 at the frontside. In some embodiments, the semiconductor device 100a has a via 184 connecting a VDD through the power line 160P-1 at the backside. In some embodiments, the via 183 overlaps the via 184 along the Z direction.

In a comparative example, both the input pin and the out pin are routed from the same side (e.g., the frontside); a reverse signal coupling may occur, which adversely affects the performance of a semiconductor device. In the embodiments of the disclosure, the input pin and the out pin are routed from dual sides. Therefore, reverse signal coupling can be avoided, thereby enhancing the performance of the semiconductor device 100a.

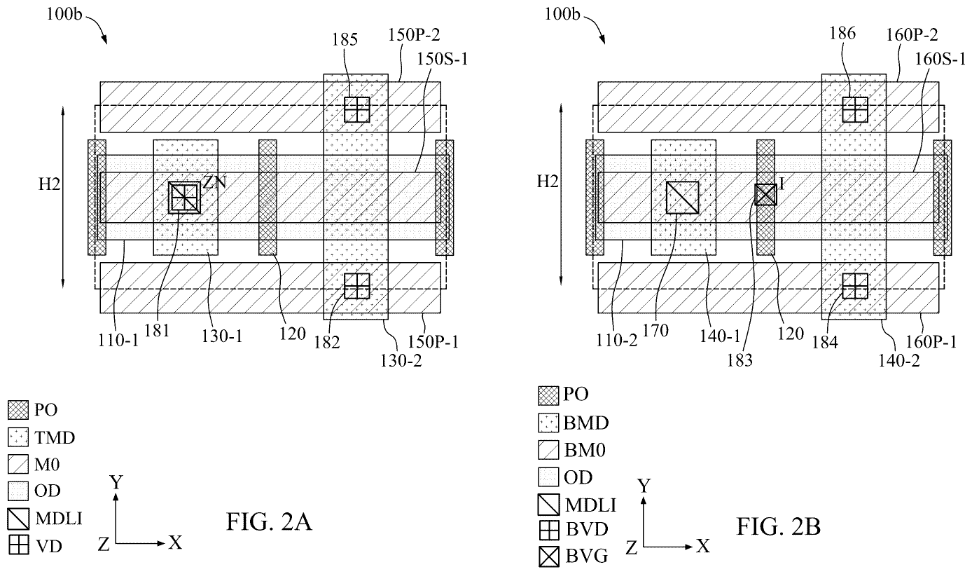

FIG. 2A and FIG. 2B are layout diagrams of a semiconductor device 100b, in accordance with some embodiments. The semiconductor device 100b has a layout similar to that of the semiconductor device 100a. One of the differences between the semiconductor devices 100b and 100a is that the signal lines 150S-2 and 160S-2 are replaced with power lines 150P-2 and 160P-2, respectively.

In some embodiments, the power line 150P-2 is electrically connected to a logic low power supply or VSS. In some embodiments, the signal line 150S-1, power line 150P-1, and power line 150P-2 constitute the M0 layer of the semiconductor device 100b. In some embodiments, the power line 150P-2 is located at a cell boundary of the cell and can be shared with another cell. In some embodiments, the power line 160P-2 is electrically connected to a logic high power supply or VDD. In some embodiments, the signal line 160S-1, power line 160P-1, and power line 160P-2 constitute the BM0 layer of the semiconductor device 100b. In some embodiments, the power line 160P-2 is located at a cell boundary of the cell and can be shared with another cell.

The semiconductor device 100 b includes a via 185. The via 185 electrically connects the contact 130-2 and power line 150P-2. The semiconductor device 100b includes a via 186. The via 186 electrically connects the contact 140-2 and power line 160P-2. In some embodiments, the via 185 overlaps the via 186 along the Z direction.

In some embodiments, the cell height H2 of the semiconductor device 100b is satisfied with an equation: H2=1×A+1×B+2×C, wherein A is a width of the signal line along the Y direction, B is a width of the power line along the Y direction, and C is a space (or distance along the Y direction) between the abutting two layers of the M0 layer. In this embodiment, more power lines are used, which can be configured to transmit a greater supply voltage.

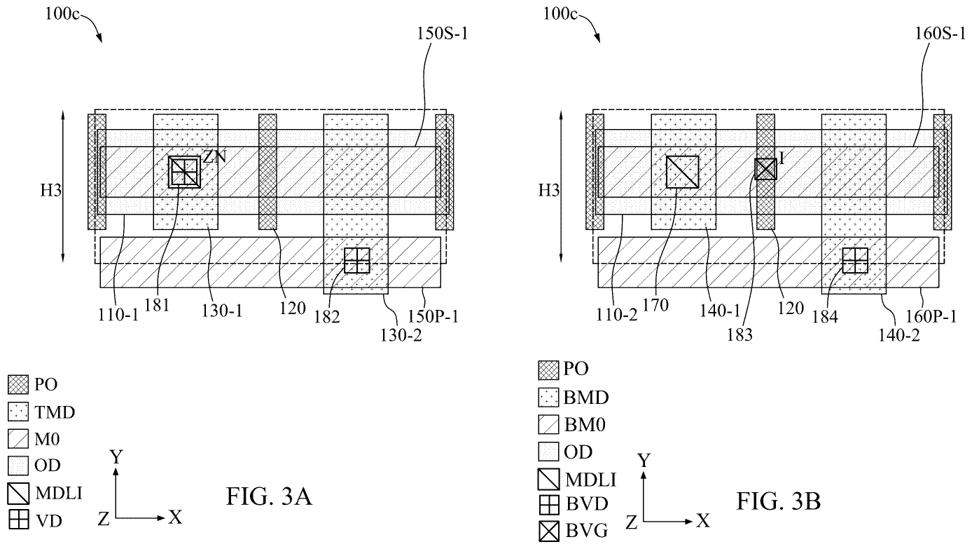

FIG. 3A and FIG. 3B are layout diagrams of a semiconductor device 100c, in accordance with some embodiments. The semiconductor device 100c has a layout similar to that of the semiconductor device 100a. One of the differences between the semiconductor devices 100c and 100a is that the signal lines 150S-2 and 160S-2 are omitted. In some embodiments, the signal line 150S-1 and power line 150P-1 constitute the M0 layer of the semiconductor device 100c. In some embodiments, the signal line 160S-1 and power line 160P-1 constitute the BM0 layer of the semiconductor device 100c.

In some embodiments, the cell height H3 of the semiconductor device 100c is satisfied with an equation: H3=1×A+0.5×B+1.5×C, wherein A is a width of the signal line along the Y direction, B is a width of the power line along the Y direction, and C is a space (or distance along the Y direction) between the abutting two layers of the M0 layer. In this embodiment, one of the power line or signal line is omitted. Therefore, the cell height of the semiconductor device 100c can be further reduced.

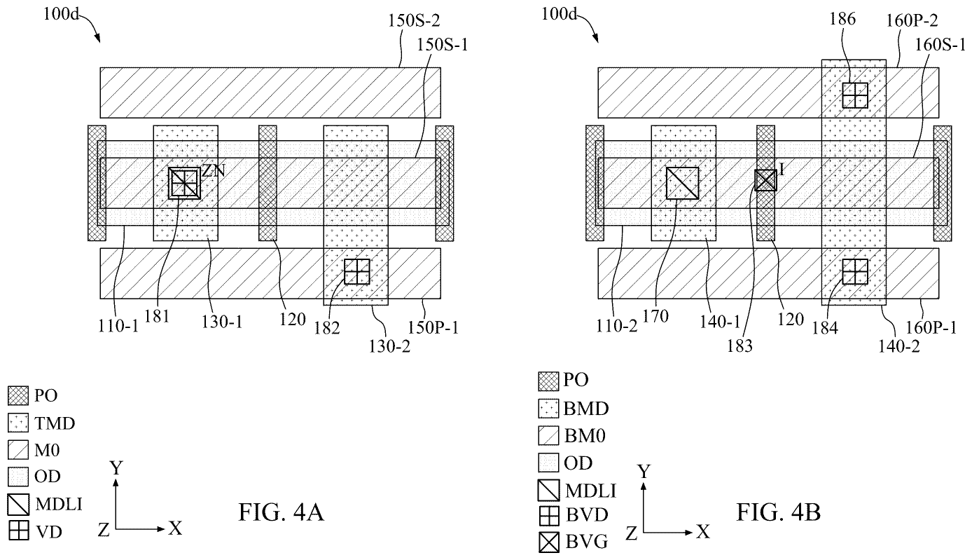

FIG. 4A and FIG. 4B are layout diagrams of a semiconductor device 100d, in accordance with some embodiments. The semiconductor device 100d has a layout similar to that of the semiconductor device 100a. One of the differences between the semiconductor devices 100d and 100a is that the signal line 160S-1, power line 160P-1, and power line 160P-2 constitute the BM0 layer of the semiconductor device 100d.

In some embodiments, the signal line 150S-2 overlaps the power line 160P-2 along the Z direction. In some embodiments, the number of power line(s) at the frontside differs from that at the backside. In some embodiments, the number of signal line(s) at the frontside differs from that at the backside. In this embodiment, the layout at the frontside and at backside can be selected from FIGS. 1A to 3A and FIGS. 1B to 3B, respectively. Therefore, the layout can be adjusted for greater flexibility.

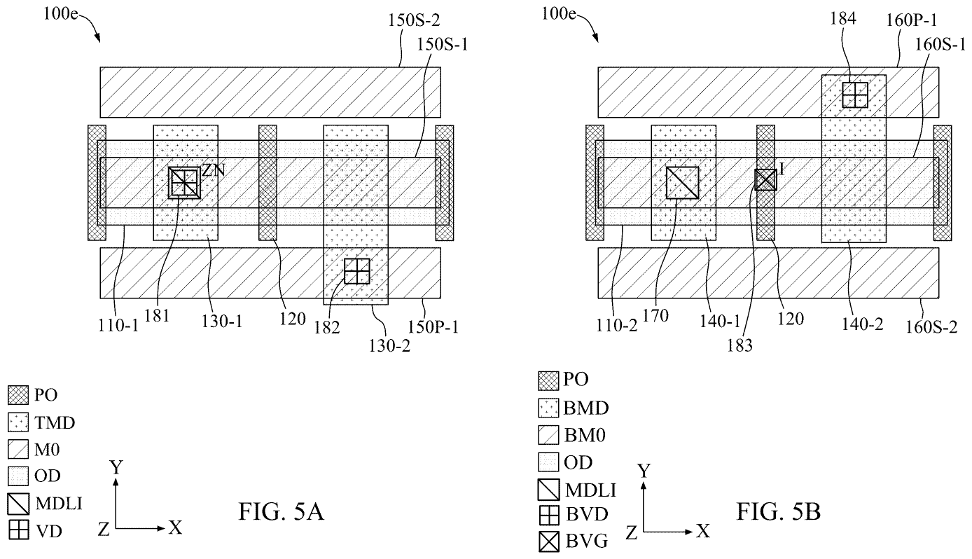

FIG. 5A and FIG. 5B are layout diagrams of a semiconductor device 100e, in accordance with some embodiments. The semiconductor device 100e has a layout similar to that of the semiconductor device 100a. One of the differences between the semiconductor devices 100e and 100a is that the power lines at the frontside and backside are staggered.

For example, the power line 150P-1 is free from overlapping the power line 160P-1 along the Z direction. In some embodiments, the power line 150P-1 overlaps the signal line 160S-2 along the Z direction. In some embodiments, the signal line 150S-2 overlaps the power line 160P-1 along the Z direction.

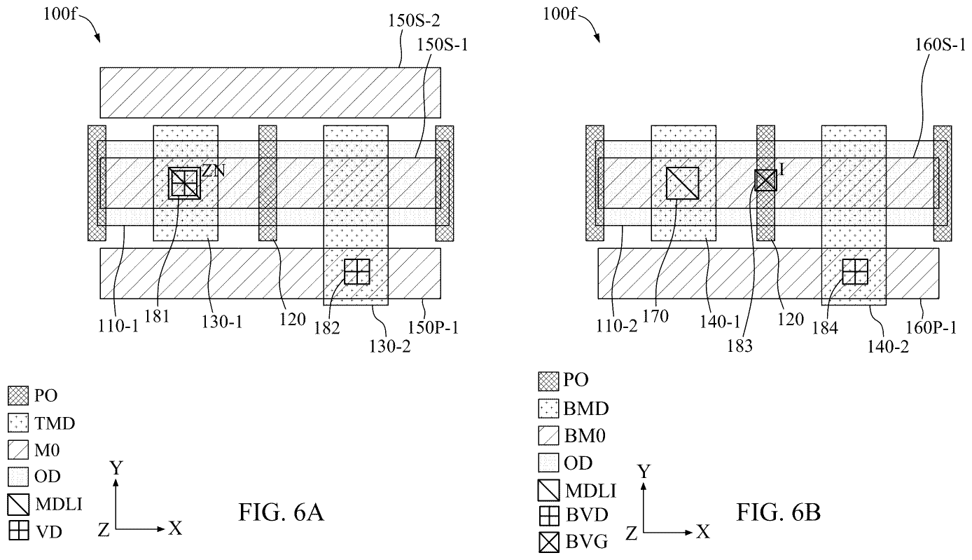

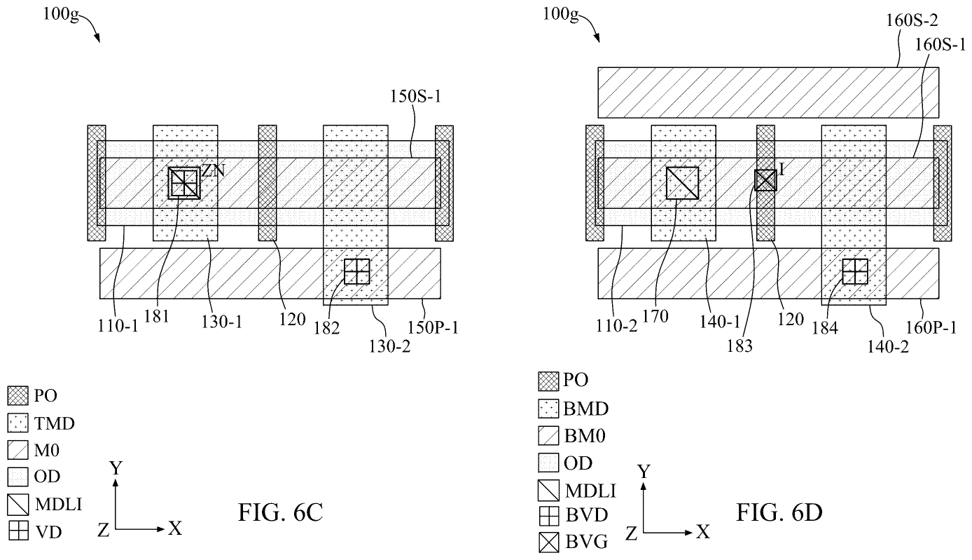

FIG. 6A and FIG. 6B are layout diagrams of a semiconductor device 100f, in accordance with some embodiments. The semiconductor device 100f has a layout similar to that of the semiconductor device 100a. One of the differences between the semiconductor devices 100f and 100a is that the number of layers of the M0 layer differs from that of the BM0 layer.

In some embodiments, the number of M0 layers is greater than the number of BM0 layers. In some embodiments, the signal line 150S-1, signal line 150S-2, and power line 150P-1 constitute the M0 layer of the semiconductor device 100f. In some embodiments, the signal line 160S-1 and power line 160P-1 constitute the BM0 layer of the semiconductor device 100f.

FIG. 6C and FIG. 6D are layout diagrams of a semiconductor device 100g, in accordance with some embodiments. The semiconductor device 100g has a layout similar to that of the semiconductor device 100a. One of the differences between the semiconductor devices 100g and 100 a is that the number of layers of the M0 layer differs from that of the BM0 layer.

In some embodiments, the number of M0 layers is fewer than the number of BM0 layers. In some embodiments, the signal line 150S-1 and power line 150P-1 constitute the M0 layer of the semiconductor device 100g. In some embodiments, the signal line 160S-1, signal line 160S-2, and power line 160P-1 constitute the BM0 layer of the semiconductor device 100g.

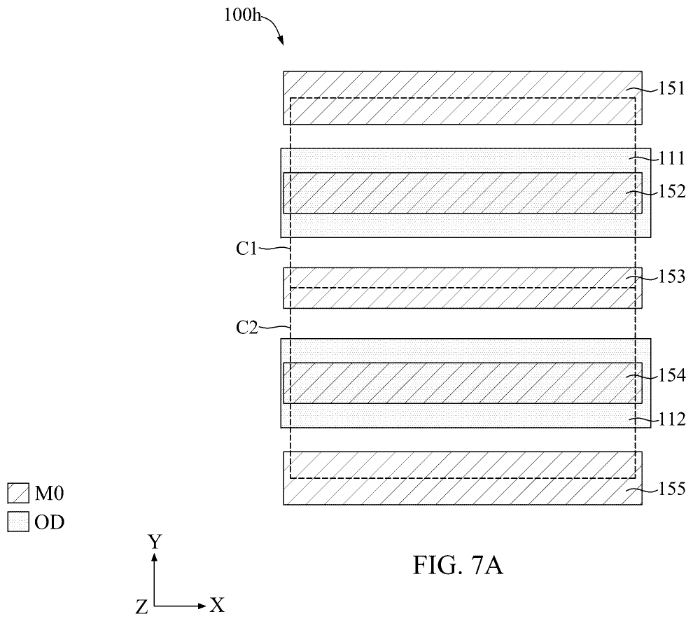

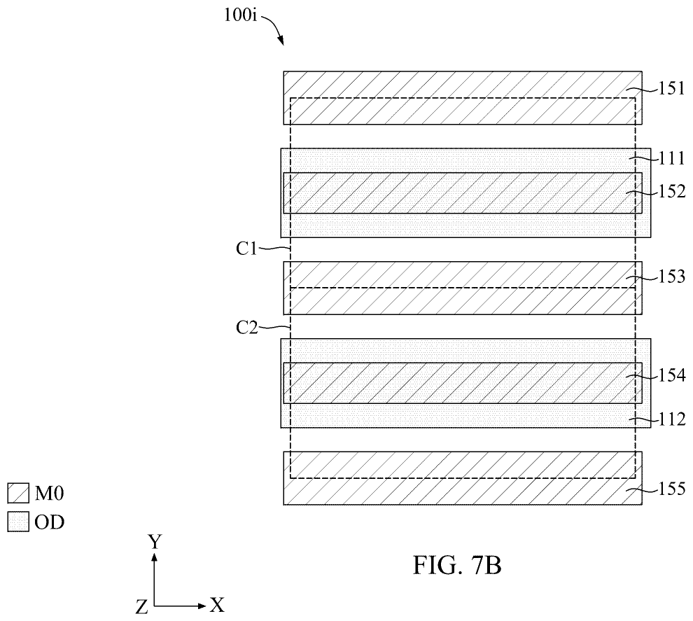

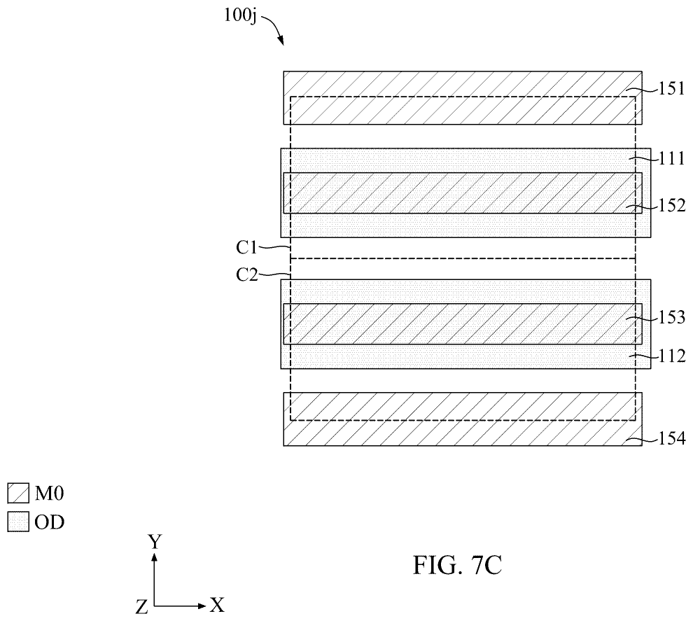

FIG. 7A is a layout diagram of a semiconductor device 100h, in accordance with some embodiments. FIG. 7A illustrates the layout of OD and M0 including two cells (e.g., the cell as shown in the semiconductor device 100a) abutted. It should be noted that other features (e.g., PO, BM0, and the like) are omitted for brevity.

The semiconductor device 100h may include a cell C1 and a cell C2 abutting the cell C1. The semiconductor device 100h may include an active region 111 within the cell C1 and an active region 112 within the cell C2. The semiconductor device 100h may include M0 layers 151, 152, 153, 154, and 155. In some embodiments, the M0 layer 153 is located at the cell boundary between the cells C1 and C2. In some embodiments, the M0 layers 151 and 155 function as power lines. In some embodiments, the M0 layers 152, 153, and 154 function as signal lines.

FIG. 7B is a layout diagram of a semiconductor device 100i, in accordance with some embodiments. FIG. 7B illustrates the layout of OD and M0 including two cells (e.g., the cell as shown in the semiconductor device 100b) abutted. It should be noted that other features (e.g., PO, BM0, and the like) are omitted for brevity.

The semiconductor device 100i may include M0 layers 151, 152, 153, 154, and 155. In some embodiments, the M0 layer 153 is located at the cell boundary between the cells C1 and C2. In some embodiments, the M0 layers 151, 153, and 155 function as power lines. In some embodiments, the M0 layers 152 and 154 function as signal lines.

FIG. 7C is a layout diagram of a semiconductor device 100j, in accordance with some embodiments. FIG. 7C illustrates the layout of OD and M0 including two cells (e.g., the cell as shown in the semiconductor device 100c) abutted. It should be noted that other features (e.g., PO, BM0, and the like) are omitted for brevity.

The semiconductor device 100j may include M0 layers 151, 152, 153, and 154. In some embodiments, the M0 layers 151 and 154 function as power lines. In some embodiments, the M0 layers 152 and 153 function as signal lines.

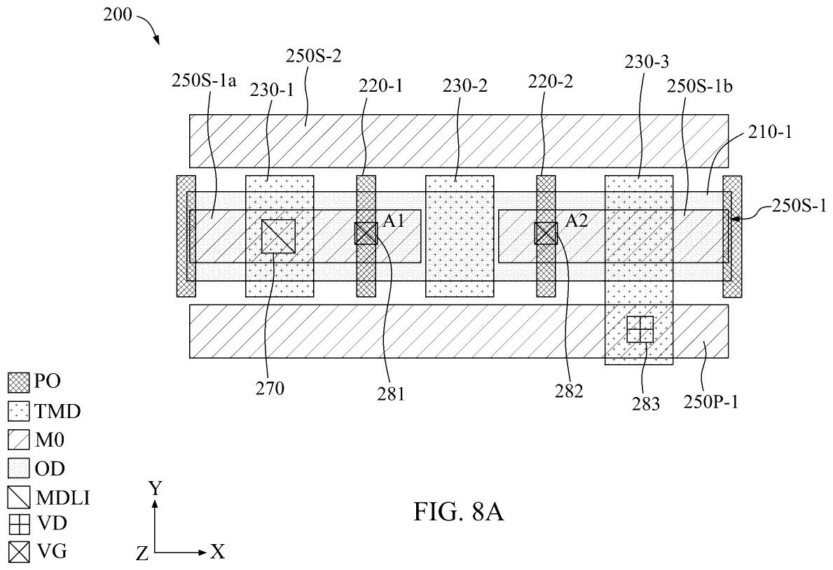

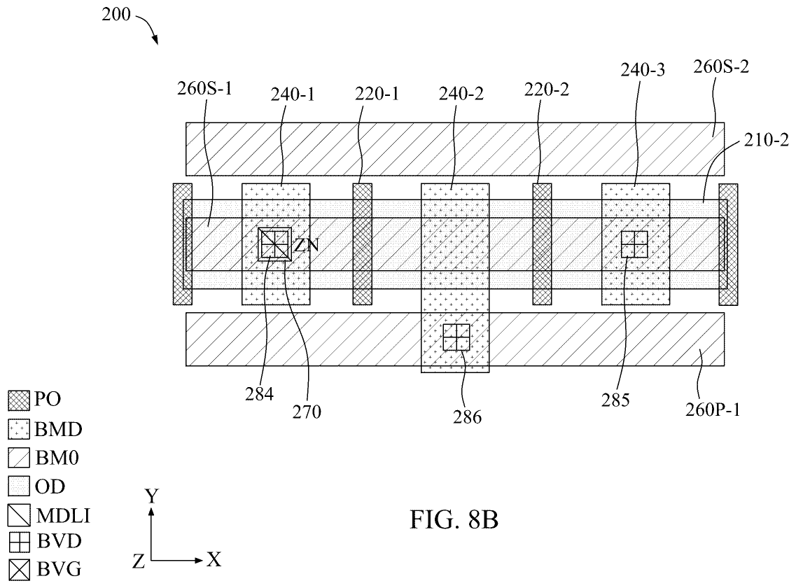

FIG. 8A and FIG. 8B are layout diagrams of a semiconductor device 200, in accordance with some embodiments.

FIG. 8A includes the layout patterns for specifying the frontside features, and FIG. 8B includes the layout patterns for specifying the backside features. In some embodiments, the semiconductor device 200 includes a layout of a cell (e.g., standard cell) of logic gates of NAND.

In some embodiments, the semiconductor device 200 includes active regions 210-1 and 210-2. In some embodiments, the active region 210-1 includes the first type (e.g., n-type) active region, and the active region 210-2 includes the second type (e.g., p-type) active region. In some embodiments, the active region 210-1 overlaps the active region 210-2 along the Z direction.

The semiconductor device 200 includes gate structures 220-1 and 220-2. In some embodiments, the gate structures 220-1 and 220-2 intersect the active region 210-1 at the channel region of the transistor with the first type, and intersect the active region 210-2 at the channel region of the transistor with the second type.

The semiconductor device 200 includes contacts 230-1, 230-2 and 230-3. The contacts 230-1 to 230-3 are disposed at the frontside of the semiconductor device 200. The contacts 230-1 to 230-3 intersect the active region 210-1 at the S/D region of the transistor with the first type.

The semiconductor device 200 includes contacts 240-1, 240-2 and 240-3. The contacts 240-1 to 240-3 are disposed at the backside of the semiconductor device 200. The contacts 240-1 to 240-3 intersect the active region 210-2 at the S/D region of the transistor with the second type.

In some embodiments, the semiconductor device 200 includes signal lines 250S-1 and 250S-2. In some embodiments, the signal line 250S-1 and/or 250S-2 can be configured to transmit a non-power signal, such as an output signal. The signal line 250S-1 includes a portion 250S-1a and a portion 250S-1b physically spaced apart from the portion 250S-1a. The portion 250S-1a overlaps the gate structure 220-1 and the contact 230-1 along the Z direction. The portion 250S-1b overlaps the gate structure 220-2 and the contact 230-3 along the Z direction.

In some embodiments, the semiconductor device 200 includes a power line 250P-1. In some embodiments, the power line 250P-1 can be configured to transmit a power signal (or power). In some embodiments, the power line 250P-1 is electrically connected to a logic low power supply or VSS. In some embodiments, the signal line 250S-1, signal line 250S-2, and power line 250P-1 constitute the M0 layer of the semiconductor device 200. In some embodiments, the signal line 250S-2 is located at a cell boundary of the cell and can be shared with another cell. In some embodiments, the power line 250P-1 is located at a cell boundary of the cell and can be shared with another cell.

In some embodiments, the semiconductor device 200 includes signal lines 260S-1 and 260S-2. In some embodiments, the signal line 260S-1 and/or 260S-2 can be configured to transmit a non-power signal, such as an output signal.

In some embodiments, the semiconductor device 200 includes a power line 260P-1. In some embodiments, the power line 260P-1 is electrically connected to a logic high power supply or VDD. In some embodiments, the signal line 260S-1, signal line 260S-2, and power line 260P-1 constitute the BM0 layer of the semiconductor device 200. In some embodiments, the signal line 260S-2 is located at a cell boundary of the cell and can be shared with another cell. In some embodiments, the power line 260P-1 is located at a cell boundary of the cell and can be shared with another cell.

The semiconductor device 200 includes a via 270 (or interconnection). The via 270 can be configured to electrically couple the TMD and the BMD. For example, the via 270 electrically connects the contact 230-1 and contact 240-1.

The semiconductor device 200 includes vias 281, 282, 283, 284, 285, and 286 (or interconnections). The via 281 and via 282 can electrically couple the PO and the M0. For example, the via 281 electrically connects the gate structure 220-1 and portion 250S-1a of the signal line 250S-1, and the via 282 electrically connects the gate structure 220-2 and portion 250S-1b of the signal line 250S-1. The via 281 and via 282 can be referred to as “VG.” The via 283 can be configured to electrically couple the TMD and the M0. For example, the via 283 electrically connects the contact 230-3 and power line 250P-1. The vias 284, 285, and 286 can electrically couple the BMD and the BM0. For example, the via 284 electrically connects the contact 240-1 and signal line 260S-1, the via 285 electrically connects the contact 240-3 and signal line 260S-1, and the via 286 electrically connects the contact 240-2 and power line 260P-1.

In some embodiments, the semiconductor device 200 has two input pins A1 and A2. The input pin A1 is routed from the gate structure 220-1 through the portion 250S-1a of the signal line 250S-1 at the frontside. The input pin A2 is routed from the gate structure 220-2 through the portion 250S-1b of the signal line 250S-1 at the frontside. In some embodiments, the output pin ZN of the semiconductor device 200 is routed from the contact 240-1 through the signal line 260S-1 at the backside. The contact 240-1 is electrically coupled to the contact 240-3 through the via 284, the via 285, and the signal line 260S-1. In addition, a VDD is provided to the semiconductor device 200 through the power line 250P-1 at the frontside; and a VSS is provided to the semiconductor device 200 through the power line 260P-1 at the backside.

Although FIGS. 7A and 7B illustrate that the power line 260P-1 overlaps the power line 250P-1, the power line 250P-1 is free from overlapping the power line 260P-1 in other embodiments. Further, the layout of the M0 and BM0 layers as well as other features as shown in FIGS. 2 to 6 can be applied to the semiconductor device 200.

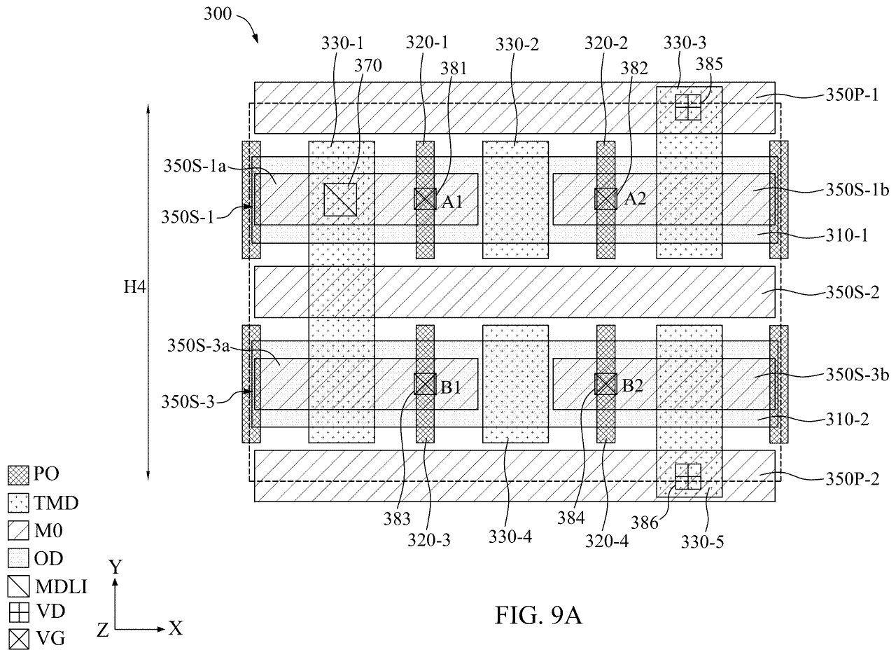

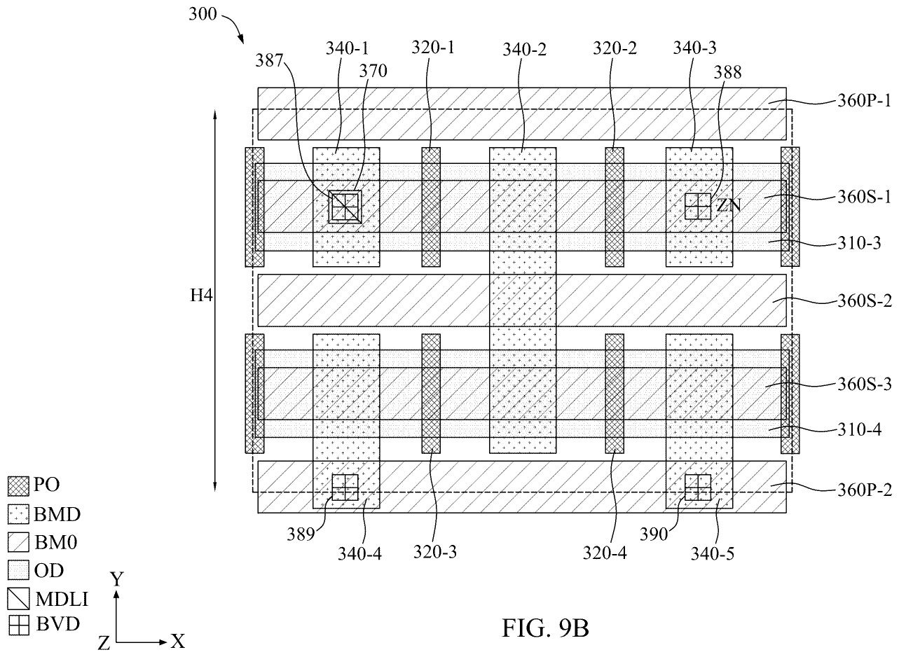

FIG. 9A and FIG. 9B are layout diagrams of a semiconductor device 300, in accordance with some embodiments. In some embodiments, the semiconductor device 300 includes a layout of a cell (e.g., standard cell) of an AND-OR-Invert (AOI) logic circuit.

In some embodiments, the semiconductor device 300 includes active regions 310-1, 310-2, 310-3, and 310-4. In some embodiments, the active regions 310-1 and 310-2 include the first type (e.g., n-type) active region, and the active regions 310-3 and 310-4 include the second type (e.g., p-type) active region.

The semiconductor device 300 includes gate structures 320-1, 320-2, 320-3, and 320-4. In some embodiments, the gate structures 320-1 and 320-2 intersect the active region 310-1 at the channel region of the transistor with the first type, and intersect the active region 310-3 at the channel region of the transistor with the second type. In some embodiments, the gate structures 320-3 and 320-4 intersect the active region 310-2 at the channel region of the transistor with the first type, and intersect the active region 310-4 at the channel region of the transistor with the second type.

The semiconductor device 300 includes contacts 330-1, 330-2, 330-3, 330-4, and 330-5. The contacts 330-1 to 330-5 are disposed at the frontside of the semiconductor device 300. The contacts 330-1 to 330-3 intersect the active region 310-1 at the S/D region of the transistor with the first type. The contacts 330-1, 330-4, and 330-5 intersect the active region 310-2 at the S/D region of the transistor with the first type.

The semiconductor device 300 includes contacts 340-1, 340-2, 340-3, 340-4, and 340-5. The contacts 340-1 to 340-5 are disposed at the backside of the semiconductor device 300. The contacts 340-1 to 340-3 intersect the active region 310-3 at the S/D region of the transistor with the second type. The contacts 340-2, 340-4, and 340-5 intersect the active region 310-4 at the S/D region of the transistor with the second type.

In some embodiments, the semiconductor device 300 includes signal lines 350S-1, 350S-2, and 350S-3. In some embodiments, the signal line 350S-1, 350-2, and/or 350S-3 can be configured to transmit a non-power signal, such as an output signal. The signal line 350S-1 includes a portion 350S-1a and a portion 350S-1b physically spaced apart from the portion 350S-1a. The signal line 350S-3 includes a portion 350S-3a and a portion 350S-3b physically spaced apart from the portion 350S-3a.

In some embodiments, the semiconductor device 300 includes power lines 350P-1 and 350P-2. In some embodiments, the power lines 350P-1 and 350P-2 can be configured to transmit a power signal (or power). In some embodiments, the power lines 350P-1 and 350P-2 are electrically connected to a logic low power supply or VSS. In some embodiments, the signal lines 350S-1 to 350S-3 and power lines 350P-1 to 350P-2 constitute the M0 layer of the semiconductor device 300.

In some embodiments, the semiconductor device 300 includes signal lines 360S-1, 360S-2, and 360S-3. In some embodiments, the signal line 360S-1, 360-2, and/or 360S-3 can be configured to transmit a non-power signal, such as an output signal.

In some embodiments, the semiconductor device 300 includes power lines 360P-1 and 360P-2. In some embodiments, the power lines 360P-1 and 360P-2 can be configured to transmit a power signal (or power). In some embodiments, the power lines 360P-1 and 360P-2 are electrically connected to a logic high power supply or VDD. In some embodiments, the signal lines 360S-1 to 360S-3 and power lines 360P-1 to 360P-2 constitute the BM0 layer of the semiconductor device 300.

The semiconductor device 300 includes a via 370 (or interconnection). The via 370 can be configured to electrically couple the TMD and the BMD. For example, the via 370 electrically connects the contact 330-1 and contact 340-1.

The semiconductor device 300 includes vias 381, 382, 383, 384, 385, 386, 387, 388, 389, and 390 (or interconnections). The vias 381 to 384 can electrically couple the PO and the M0. For example, the via 381 electrically connects the gate structure 320-1 and portion 350S-1a of the signal line 350S-1, the via 382 electrically connects the gate structure 320-2 and portion 350S-1b of the signal line 350S-1, the via 383 electrically connects the gate structure 320-3 and portion 350S-3a of the signal line 350S-3, and the via 384 electrically connects the gate structure 320-4 and portion 350S-3b of the signal line 350S-3. The vias 385 and 386 can be configured to electrically couple the TMD and the M0. For example, the via 385 electrically connects the contact 330-3 and power line 350P-1, and the via 386 electrically connects the contact 330-5 and power line 350P-2. The vias 387 to 390 can electrically couple the BMD and the BM0. For example, the via 387 electrically connects the contact 340-1 and signal line 360S-1, the via 388 electrically connects the contact 340-3 and signal line 360S-1, the via 389 electrically connects the contact 340-4 and power line 360P-2, and the via 390 electrically connects the contact 340-5 and power line 360P-2.

In some embodiments, the semiconductor device 300 has four input pins A1, A2, B1, and B2. The input pin A1 is routed from the gate structure 320-1 through the portion 350S-1a of the signal line 350S-1 at the frontside. The input pin A2 is routed from the gate structure 320-2 through the portion 350S-1b of the signal line 350S-1 at the frontside. The input pin B1 is routed from the gate structure 320-3 through the portion 350S-3a of the signal line 350S-3 at the frontside. The input pin B2 is routed from the gate structure 320-4 through the portion 350S-3b of the signal line 350S-3 at the frontside. In some embodiments, the output pin ZN of the semiconductor device 300 is routed from the contact 340-3 through the signal line 360S-1 at the backside. The contact 340-1 is electrically coupled to the contact 340-3 through the via 387, the via 388, and the signal line 360S-1. In addition, a VDD is provided to the semiconductor device 300 through the power line 350P-1 and the power line 350P-2 at the frontside; and a VSS is provided to the semiconductor device 300 through the power line 360P-2 at the backside.

In some embodiments, the cell height H4 of the semiconductor device 300 is satisfied with an equation: H4=2×(1.5×A+0.5×B+2×C), wherein A is a width of the signal line along the Y direction, B is a width of the power line along the Y direction, and C is a space (or distance along the Y direction) between the abutting two layers of the M0 layer.

In some embodiments, the layout of the M0 and BM0 layers as well as other features as shown in FIGS. 2 to 6 can be applied to the semiconductor device 300.

The embodiments of the present disclosure provide a layout of a cell of a semiconductor device with a cell height H satisfied with an equation: H=n ×(i×A+j×B+k×C), wherein A is a width of the signal line along the Y direction, B is a width of the power line along the Y direction, and C is a space (or distance along the Y direction) between the abutting two layers of the M0 layer, and wherein i is 1 or 1.5, j is 0.5 or 1, k is 1.5 or 2, and n is a natural number, such as 1, 2, 3, or the like.

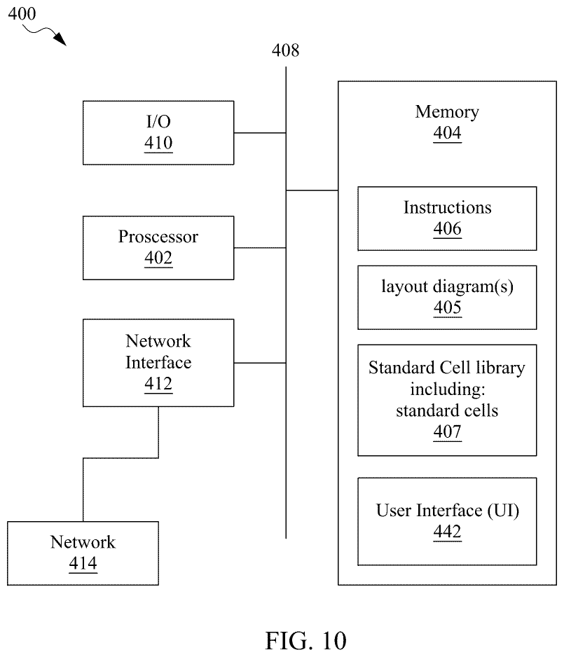

FIG. 10 is a block diagram of a system 400 of designing a semiconductor device, in accordance with some embodiments. The system 400 can include, for example, an electronic design automation (EDA) system.

In some embodiments, system 400 includes an automatic placement and routing (APR) system. Methods described herein of generating PG layout diagrams, in accordance with one or more embodiments, are implementable, for example, using the system 400, in accordance with some embodiments.

In some embodiments, system 400 is a general purpose computing device including a hardware processor 402 and a non-transitory, computer-readable storage medium 404. Storage medium 404, amongst other things, is encoded with, i.e., stores, computer program code 406, i.e., a set of executable instructions. Execution of instructions 406 by hardware processor 402 represents (at least in part) an EDA tool which implements a portion or all of a method according to an embodiment, e.g., the methods described herein in accordance with one or more embodiments. (hereinafter, the noted processes and/or methods).

Processor 402 is electrically coupled to computer-readable storage medium 404 via a bus 408. Processor 402 is also electrically coupled to an I/O interface 410 by bus 408. A network interface 412 is also electrically connected to processor 402 via bus 408. Network interface 412 is connected to a network 414, so that processor 402 and computer-readable storage medium 404 are capable of connecting to external elements via network 414. Processor 402 is configured to execute computer program code 406 encoded in computer-readable storage medium 404 in order to cause system 400 to be usable for performing a portion or all of the noted processes and/or methods. In one or more embodiments, processor 402 is a central processing unit (CPU), a multi-processor, a distributed processing system, an application specific integrated circuit (ASIC), and/or a suitable processing unit.

In one or more embodiments, computer-readable storage medium 404 is an electronic, magnetic, optical, electromagnetic, infrared, and/or semiconductor system (or apparatus or device). For example, computer-readable storage medium 404 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 404 includes a compact disk-read only memory (CD-ROM), a compact disk-read/write (CD-R/W), and/or a digital video disc (DVD).

In one or more embodiments, storage medium 404 stores computer program code (instructions) 406 configured to cause system 400 (where such execution represents (at least in part) the EDA tool) to be usable for performing a portion or all of the noted processes and/or methods. In one or more embodiments, storage medium 404 also stores information which facilitates performing a portion or all of the noted processes and/or methods. In one or more embodiments, storage medium 404 stores library 407 of cells including such cells as disclosed herein and one or more layout diagrams 405 such as are disclosed herein.

System 400 includes I/O interface 410. I/O interface 410 is coupled to external circuitry. In one or more embodiments, I/O interface 410 includes a keyboard, keypad, mouse, trackball, trackpad, touchscreen, and/or cursor direction keys for communicating information and commands to processor 402.

System 400 also includes network interface 412 coupled to processor 402. Network interface 412 allows system 400 to communicate with network 414, to which one or more other computer systems are connected. Network interface 412 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 400.

System 400 is configured to receive information through I/O interface 410. The information received through I/O interface 410 includes one or more of instructions, data, design rules, libraries of cells, and/or other parameters for processing by processor 402. The information is transferred to processor 402 via bus 408. System 400 is configured to receive information related to a UI through I/O interface 410. The information is stored in computer-readable medium 404 as user interface (UI) 442.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods are implemented as a software application running on System 400. In some embodiments, a layout diagram which includes cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

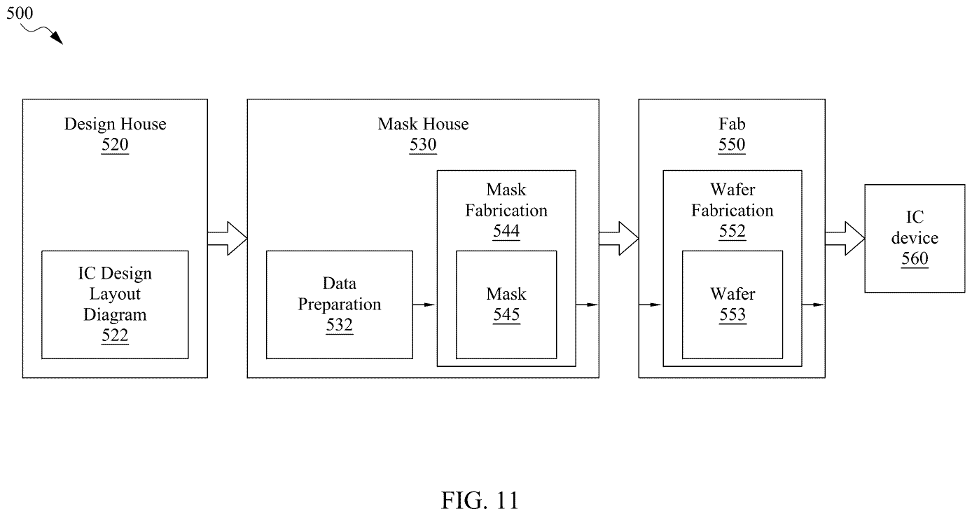

FIG. 11 is a block diagram of a semiconductor device manufacturing system 500, and a semiconductor device flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 500.

In FIG. 11, IC manufacturing system 500 includes entities, such as a design house 520, a mask house 530, and an IC manufacturer/fabricator (“fab”) 550, that interact with one another in the design, development, and manufacturing cycles and/or services related to manufacturing an IC device 560. The entities in system 500 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 520, mask house 530, and IC fab 550 is owned by a single larger company. In some embodiments, two or more of design house 520, mask house 530, and IC fab 550 coexist in a common facility and use common resources.

Design house (or design team) 520 generates an IC design layout diagram 522. IC design layout diagram 522 includes various geometrical patterns designed for an IC device 560. The geometrical patterns correspond to patterns of metal, oxide, or semiconductor layers that make up the various components of IC device 560 to be fabricated. The various layers combine to form various IC features. For example, a portion of IC design layout diagram 522 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 520 implements a proper design procedure to form IC design layout diagram 522. The design procedure includes one or more of logic design, physical design or place and route. IC design layout diagram 522 is presented in one or more data files having information of the geometrical patterns. For example, IC design layout diagram 522 can be expressed in a GDSII file format or DFII file format.

Mask house 530 includes data preparation 532 and mask fabrication 544. Mask house 530 uses IC design layout diagram 522 to manufacture one or more masks 545 to be used for fabricating the various layers of IC device 560 according to IC design layout diagram 522. Mask house 530 performs mask data preparation 532, where IC design layout diagram 522 is translated into a representative data file (“RDF”). Mask data preparation 532 provides the RDF to mask fabrication 544. Mask fabrication 544 includes a mask writer. A mask writer converts the RDF to an image on a substrate, such as a mask (reticle) 545 or a semiconductor wafer 553. The design layout diagram 522 is manipulated by mask data preparation 532 to comply with particular characteristics of the mask writer and/or requirements of IC fab 550. In FIG. 11, mask data preparation 532 and mask fabrication 544 are illustrated as separate elements. In some embodiments, mask data preparation 532 and mask fabrication 544 can be collectively referred to as mask data preparation.

In some embodiments, mask data preparation 532 includes optical proximity correction (OPC) which uses lithography enhancement techniques to compensate for image errors, such as those that can arise from diffraction, interference, other process effects and the like. OPC adjusts IC design layout diagram 522. In some embodiments, mask data preparation 532 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 532 includes a mask rule checker (MRC) that checks the IC design layout diagram 522 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 522 to compensate for limitations during mask fabrication 544, which may undo part of the modifications performed by OPC in order to meet mask creation rules.

In some embodiments, mask data preparation 532 includes lithography process checking (LPC) that simulates processing that will be implemented by IC fab 550 to fabricate IC device 560. LPC simulates this processing based on IC design layout diagram 522 to create a simulated manufactured device, such as IC device 560. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 522.

It should be understood that the foregoing description of mask data preparation 532 has been simplified for the purposes of clarity. In some embodiments, data preparation 532 includes additional features such as a logic operation (LOP) to modify the IC design layout diagram 522 according to manufacturing rules. Additionally, the processes applied to IC design layout diagram 522 during data preparation 532 may be executed in a variety of different orders.

After mask data preparation 532 and during mask fabrication 544, a mask 545 or a group of masks 545 are fabricated based on the modified IC design layout diagram 522. In some embodiments, mask fabrication 544 includes performing one or more lithographic exposures based on IC design layout diagram 522. In some embodiments, an electron-beam (e-beam) or a mechanism of multiple e-beams is used to form a pattern on a mask (photomask or reticle) 545 based on the modified IC design layout diagram 522. Mask 545 can be formed in various technologies. In some embodiments, mask 545 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 545 includes a transparent substrate (e.g., fused quartz) and an opaque material (e.g., chromium) coated in the opaque regions of the binary mask. In another example, mask 545 is formed using a phase shift technology. In a phase shift mask (PSM) version of mask 545, various features in the pattern formed on the phase shift mask are configured to have proper phase difference to enhance the resolution and imaging quality. In various examples, the phase shift mask can be attenuated PSM or alternating PSM. The masks generated by mask fabrication 544 are used in a variety of processes. For example, such a mask(s) can be used in an ion implantation process to form various doped regions in semiconductor wafer 553, in an etching process to form various etching regions in semiconductor wafer 553, and/or in other suitable processes.

IC fab 550 includes wafer fabrication 552. IC fab 550 is an IC fabricator that includes one or more manufacturing facilities for the fabrication of a variety of different IC products. In some embodiments, IC Fab 550 can be a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 550 uses mask(s) 545 fabricated by mask house 530 to fabricate IC device 560. Thus, IC fab 550 at least indirectly uses IC design layout diagram 522 to fabricate IC device 560. In some embodiments, semiconductor wafer 553 is fabricated by IC fab 550 using mask(s) 545 to form IC device 560. In some embodiments, the IC fabrication includes performing one or more lithographic exposures based at least indirectly on IC design layout diagram 522. Semiconductor wafer 553 includes a silicon substrate or other proper substrate having material layers formed thereon. Semiconductor wafer 553 further includes one or more of various doped regions, dielectric features, multilevel interconnects, and the like (formed at subsequent manufacturing steps).

Details regarding an integrated circuit (IC) manufacturing system (e.g., system 500 of FIG. 11), and an IC manufacturing flow associated therewith are found, e.g., in U.S. Pat. No. 9,256,709, granted Feb. 9, 2016, U.S. Pre-Grant Publication No. 20150278429, published Oct. 1, 2015, U.S. Pre-Grant Publication No. 20140040838, published Feb. 6, 2014, and U.S. Pat. No. 7,260,442, granted Aug. 21, 2007, the entireties of each of which are hereby incorporated by reference.

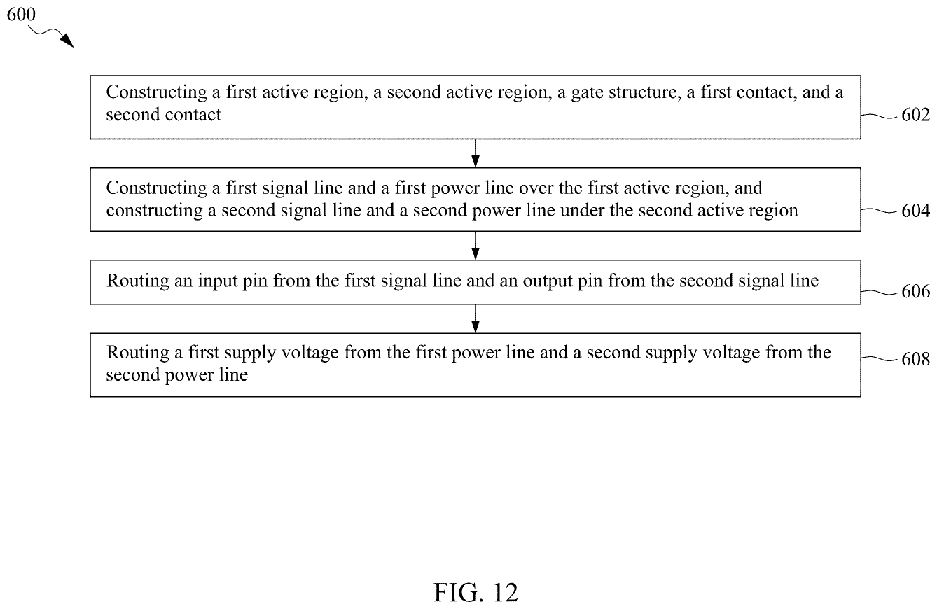

FIG. 12 is a flowchart of a method 600 for manufacturing a semiconductor device (e.g., the semiconductor devices 100a to 300) according to various aspects of the present disclosure.

The method 600 begins with operation 602 in which a first active region, a second active region, a gate structure, a first contact, and a second contact are constructed.

The method 600 continues with operation 604 in which a first signal line and a first power line are constructed over the first active region, and a second signal line and a second power line are constructed under the second active region.

The method 600 continues with operation 606 in which an input pin is routed from the first signal line, and an output pin is routed from the second signal line.

The method 600 continues with operation 608 in which a first supply voltage is routed from the first power line, and a second supply voltage is routed from the second power line.

The method 600 is merely an example, and is not intended to limit the present disclosure beyond what is explicitly recited in the claims. Additional operations can be provided before, during, and after the method 600, and some operations described can be replaced, eliminated, or reordered for additional embodiments of the method.

Some embodiments of the present disclosure provide a semiconductor device. The semiconductor device has a cell. The cell includes a gate structure, a first active region, a second active region, a first signal line, and a second signal line. The gate structure extends along a first direction. The first active region extends along a second direction different from the first direction and intersects the gate structure. The second active region extends along the second direction and intersects the gate structure. The first active region overlaps the second active region along a third direction different from the first direction and the second direction. The first signal line is over the first active region and configured to transmit an input signal. The second signal line is under the second active region and configured to transmit an output signal.

Some embodiments of the present disclosure provide a semiconductor device. The semiconductor device has a cell. The cell includes a gate structure, a first active region, a second active region, at least one first non-power line, and at least one first power line. The gate structure extends along a first direction. The first active region extends along a second direction different from the first direction and intersects the gate structure. The second active region extends along the second direction and intersects the gate structure. The first active region overlaps the second active region along a third direction different from the first direction and the second direction. The at least one first non-power line is over the first active region. The at least one first power line is over the first active region and located a level the same as that of the first non-power line. A cell height of the cell is H, which is satisfied with an equation: H=i ×A+j×B+k×C. A is a width of the first signal line along the first direction, B is a width of the at least one first power line along the first direction, and C is a space between the at least one first power line and the first signal line. i is 1 or 1.5, j is 0.5 or 1, and k is less than or equal to 2.

Some embodiments of the present disclosure provide a method of manufacturing a semiconductor device. The method includes: constructing a gate structure extending along a first direction; constructing a first active region extending along a second direction different from the first direction and intersecting the gate structure; constructing a second active region extending along the and intersecting the gate structure, wherein the first active region overlaps the second active region along a third direction different from the first direction and the second direction; constructing a first signal line over the first active region and configured to transmit an input signal; and constructing a second signal line under the second active region and configured to transmit an output signal.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device having cell, the cell comprising:
a gate structure extending along a first direction;
a first active region extending along a second direction different from the first direction and intersecting the gate structure;
a second active region extending along the second direction and intersecting the gate structure, wherein the first active region overlaps the second active region along a third direction different from the first direction and the second direction;
a first signal line over the first active region and configured to transmit an input signal; and
a second signal line under the second active region and configured to transmit an output signal.

2. The semiconductor device of claim 1, further comprising:
at least one first power line located at a first level the same as that of the first signal line; and
at least one second power line located at a second level the same as that of the second signal line.

3. The semiconductor device of claim 2, wherein the at least one first power line is free from overlapping the at least one second power line along the third direction.

4. The semiconductor device of claim 2, wherein the first signal line is free from overlapping the second signal line along the third direction.

5. The semiconductor device of claim 2, wherein a quantity of the at least one first power line is different from a quantity of the at least one second power line within the cell.

6. The semiconductor device of claim 2, wherein the at least one first power line is located at a cell boundary of the cell, and the first signal line is located within the cell boundary of the cell.

7. The semiconductor device of claim 2, wherein a metal zero (M0) layer of the cell is constituted by one first power line and one first signal line.

8. The semiconductor device of claim 2, wherein a cell height of the cell is H, which is satisfied with an equation:
H=n×(i×A+j 33 B+k×C), wherein A is a width of the first signal line along the first direction, B is a width of the at least one first power line along the first direction, and C is a space between the at least one first power line and the first signal line, and wherein i is 1 or 1.5, j is 0.5 or 1, k is 1.5 or 2, and n is a nature number.

9. A semiconductor device having a cell, the cell comprising:
a gate structure extending along a first direction;
a first active region extending along a second direction different from the first direction and intersecting the gate structure;
a second active region extending along the second direction and intersecting the gate structure, wherein the first active region overlaps the second active region along a third direction different from the first direction and the second direction;
at least one first non-power line over the first active region;
at least one first power line over the first active region and located a level the same as that of the first non-power line; and
wherein a cell height of the cell is H, which is satisfied with an equation:
H=n×(i×A+j×B+k×C), wherein A is a width of the least one first non-power line along the first direction, B is a width of the at least one first power line along the first direction, and C is a space between the at least one first power line and the least one first non-power line, and wherein i is 1 or 1.5, j is 0.5 or 1, k is 1.5 or 2, and n is a nature number.

10. The semiconductor device of claim 9, wherein k is 1.5.

11. The semiconductor device of claim 9, further comprising:
at least one second power line under the second active region.

12. The semiconductor device of claim 11, wherein a quantity of the at least one first power line is different from a quantity of the at least one second power line within the cell.

13. The semiconductor device of claim 9, wherein j is 1.

14. The semiconductor device of claim 11, wherein the at least one first power line is free from overlapping the at least one second power line along the third direction.

15. The semiconductor device of claim 9, further comprising:
at least one second non-power line under the second active region, wherein the at least one first non-power line is configured to transmit an output signal, and the at least one second non-power line is configured to transmit an input signal.

16. The semiconductor device of claim 15, wherein a quantity of the at least one second non-power line is different from a quantity of the at least one first non-power line.

17. The semiconductor device of claim 9, further comprising:
an interconnection between the first active region and the second active region,
wherein the interconnection overlaps the at least one first non-power line along the third direction.

18. A method of manufacturing a semiconductor device, comprising:
constructing a gate structure extending along a first direction;
constructing a first active region extending along a second direction different from the first direction and intersecting the gate structure;
constructing a second active region extending along the second direction and intersecting the gate structure, wherein the first active region overlaps the second active region along a third direction different from the first direction and the second direction;
constructing a first signal line over the first active region and configured to transmit an input signal; and
constructing a second signal line under the second active region and configured to transmit an output signal.

19. The method of claim 18, further comprising:
constructing at least one first power line at a first level the same as that of the first signal line; and
constructing at least one second power line at a second level the same as that of the first signal line.

20. The method of claim 18, further comprising:
constructing an interconnection at a level between the first active region and the second active region, wherein the interconnection overlaps the first signal line along the third direction.
